(19) United States
(12) Patent Application Publication
(10) Pub. No.: US 2025/0201641 A1
(43) Pub. Date: Jun. 19, 2025

(54) SEMICONDUCTOR PACKAGES HAVING A SUBSTRATE WITH CONNECTING PORTIONS

(71) Applicant: Samsung Electronics Co., Ltd., Suwon-si (KR)

(72) Inventors: Gyuhyeong Kim, Suwon-si (KR); Jongwan Kim, Suwon-si (KR); Taejun Jeon, Suwon-si (KR); Junhyeung Jo, Suwon-si (KR)

(21) Appl. No.: 18/886,042

(22) Filed: Sep. 16, 2024

(30) Foreign Application Priority Data
Dec. 15, 2023 (KR) 10-2023-0182585

(51) Int. Cl. H01L 23/13; H01L 23/00; H01L 23/29; H01L 23/538; H01L 25/065

(52) U.S. Cl. CPC H01L 23/13; H01L 23/291; H01L 23/5386; H01L 24/48; H01L 24/73; H01L 25/0657; H01L 24/16; H01L 24/32; H01L 24/33; H01L 2224/16227; H01L 2224/32145; H01L 2224/32225; H01L 2224/33181; H01L 2224/48157; H01L 2224/73204; H01L 2224/73253; H01L 2224/73265; H01L 2225/06568

(57) ABSTRACT

A semiconductor package according to example embodiments may include: a substrate including a connecting portion including a bonding pad; a first semiconductor chip disposed on the substrate; an underfill between the substrate and the first semiconductor chip; a second semiconductor chip disposed on the first semiconductor chip; an encapsulant covering the substrate, the first semiconductor chip, and the second semiconductor chip. The bonding pad is disposed on a level higher than that of an upper pad disposed on an upper surface of the substrate.

### CROSS-REFERENCE TO RELATED APPLICATION(S)

This application claims benefit of priority to Korean Patent Application No. 10-2023-0182585 filed on Dec. 15, 2023, in the Korean Intellectual Property Office, the disclosure of which is incorporated herein by reference in its entirety.

### BACKGROUND

The present disclosure relates to semiconductor packages having connecting portions.

With an increase in demand for high performance, high speed, and/or multifunctionalization of semiconductor devices, the degree of integration of semiconductor devices is increasing. In manufacturing a fine-patterned semiconductor device corresponding to the tendency for high integration of semiconductor devices, it is necessary to implement patterns having a fine width or a fine separation distance. In addition, high integration of semiconductor devices mounted on a semiconductor package is required.

### SUMMARY

An aspect of the present disclosure is to provide a semiconductor package with a connecting portion in which a bonding pad is included at an upper surface of a substrate.

According to an aspect of the present disclosure, a semiconductor package may include: a substrate including a first region, a second region, a connecting portion in the second region, the first region of the substrate having an upper pad disposed at an upper surface thereof and the connecting portion having a bonding pad disposed at an upper surface thereof; a first semiconductor chip disposed on the substrate in the first region; an underfill between the substrate and the first semiconductor chip; a second semiconductor chip disposed on the first semiconductor chip; and an encapsulant covering the substrate, the first semiconductor chip, and the second semiconductor chip. The bonding pad may be disposed at a level higher than that of the upper pad.

According to an aspect of the present disclosure, a semiconductor package may include: a substrate having an upper surface including a first region and a second region; at least one semiconductor chip stacked on the first region of the substrate; a bonding wire electrically connecting an uppermost semiconductor chip from among the at least one semiconductor chip to the substrate; an encapsulant covering the substrate and the at least one semiconductor chip. An upper surface of the second region may be disposed at a level higher than that of an upper surface of the first region, and the substrate may include a bonding pad disposed at an upper surface of the second region.

According to an aspect of the present disclosure, a semiconductor package may include: a substrate including a connecting portion defining a cavity, the upper connection portion including a bonding pad; a first semiconductor chip disposed on the substrate and disposed in the cavity; an underfill between the substrate and the first semiconductor chip; a second semiconductor chip disposed on the first semiconductor chip; a bonding wire connecting the second semiconductor chip and the bonding pad; and an encapsulant covering the substrate, the first semiconductor chip, the second semiconductor chip, and the bonding wire. The connecting portion may be disposed to surround the first semiconductor chip. The bonding pad is disposed on a level higher than that of a lower surface of the first semiconductor chip. A lower portion of the encapsulant may be in contact with an internal surface of the connecting portion, and a side surface of an upper portion of the encapsulant may be coplanar with an external surface of the connecting portion.

According to example embodiments of the technical concept of the present disclosure, a connecting portion that includes a bonding pad is formed in a second region that is higher than a first region of an upper surface of a substrate. Therefore, it may be possible to prevent an underfill disposed between the substrate and a semiconductor chip from covering the bonding pad. In addition, an encapsulant of the present disclosure may effectively dissipate heat from a semiconductor package using a material with high thermal conductivity, and a volume of the encapsulant may be reduced by a volume of the connecting portion. Accordingly, a smaller amount of encapsulant may be used and manufacturing costs thereof may be reduced.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view of a semiconductor package according to an example embodiment;

FIG. 2 is a vertical cross-sectional view taken along line I-I of the semiconductor package illustrated in FIG. 1;

FIG. 3, FIG. 4A, FIG. 4B, and FIG. 5 are vertical cross-sectional views of a semiconductor package according to example embodiments;

FIG. 6 is a plan view of a semiconductor package according to an example embodiment;

FIG. 7 is a vertical cross-sectional view taken along line II-II′ of the semiconductor package illustrated in FIG. 6;

FIG. 8 is a plan view of a semiconductor package according to an example embodiment;

FIG. 9A is a vertical cross-sectional view of a semiconductor package according to an example embodiment;

FIG. 9B is a vertical cross-sectional view of a semiconductor package according to an example embodiment;

FIGS. 10 to 12 are diagrams for explaining a method of forming a semiconductor package according to example embodiments; and

FIGS. 13 and 14 are vertical cross-sectional views of a semiconductor package according to example embodiments.

### DETAILED DESCRIPTION

Hereinafter, example embodiments will be described with reference to the accompanying drawings. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the drawings, the size and relative sizes of layers and regions may be exaggerated for clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole into consideration.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, the singular forms “a”, “an” and “the” are intended to include the plural forms as well, unless the context clearly indicates otherwise. Similarly, the plural forms are intended to include individual items in the plurality, unless the context clearly indicates otherwise. Relationships with a plurality of items may be one-to-one, one-to-many, many-to-many, and/or many-to-one, unless the context clearly indicates otherwise. Furthermore, it will be understood that although a single item may be described, the item may be one of a plurality of items and the description of the single item is applicable to each of the plurality of items. As used herein, the term “and/or” includes any and all combinations of one or more of the associated listed items and may be abbreviated as “/”.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly. Additionally, when referring to a relationship between levels, it will be understood that the reference is with respect to a lower surface of a substrate.

It will be understood that when an element is referred to as being “connected” or “coupled” to or “on” or “disposed on” another element, it can be directly connected or coupled to or on or disposed on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

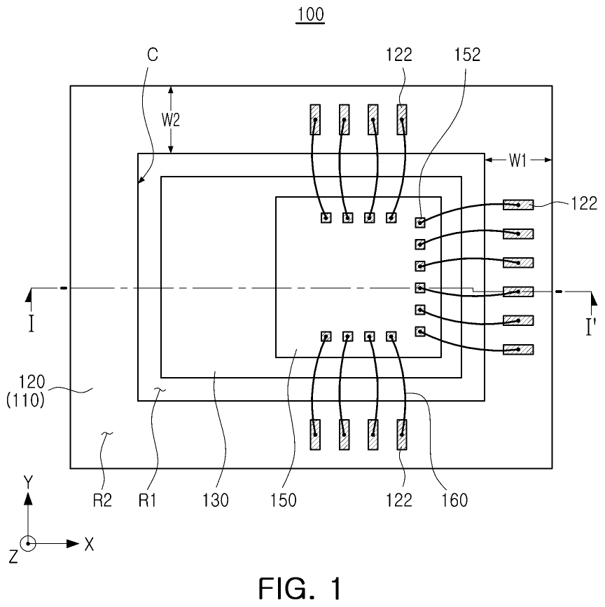

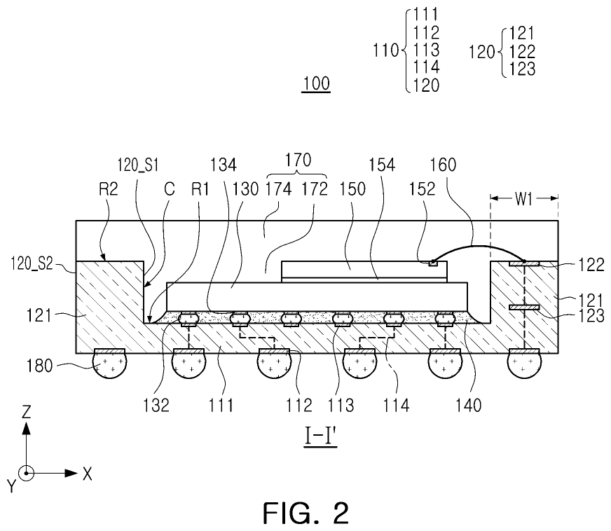

FIG. 1 is a plan view of a semiconductor package according to an example embodiment. FIG. 2 is a vertical cross-sectional view taken along line I-I of the semiconductor package illustrated in FIG. 1′.

Referring to FIGS. 1 and 2, a semiconductor package 100 according to an example embodiment of the present disclosure may include a substrate 110, a first semiconductor chip 130, an underfill 140, a second semiconductor chip 150, a bonding wire 160, an encapsulant 170, and an external connection terminal 180.

The substrate 110 may include a first insulating layer 111, a lower pad 112, an upper pad 113, an internal wiring 114, and a connecting portion 120. In an example embodiment, the substrate 110 may be a substrate for a semiconductor package, such as a printed circuit board (PCB), an interposer substrate, a ceramic substrate, or a tape wiring board. For example, in an example embodiment, the substrate 110 may be a printed circuit board (PCB).

The first insulating layer 111 of the substrate 110 may include a thermosetting resin such as epoxy resin, a thermoplastic resin such as polyimide, or a photosensitive insulating layer. Specifically, the first insulating layer 111 may include materials such as prepreg, an Ajinomoto Build-up Film (ABF)®, FR-4 (flame retardant, woven fiberglass with an epoxy binder), Bismaleimide Triazine (BT), and a photoimageable dielectric resin (PID). The first insulating layer 111 is illustrated as one layer, but the present disclosure is not limited thereto. In some example embodiments, the first insulating layer 111 may be comprised of a plurality of vertically stacked layers.

The lower pad 112 may be disposed at a lower surface of the substrate 110, and the upper pad 113 may be disposed at an upper surface of the substrate 110. For example, the lower pad 112 and the upper pad 113 may be exposed such that they are not completely covered by the first insulating layer 111. The internal wiring 114 may be disposed in the substrate 110 and may be buried within the first insulating layer 111. The lower pad 112 may be electrically connected to at least one of the internal wirings 114. The lower pad 112 may be electrically connected to at least one of the upper pads 113 through the internal wiring 114.

The lower pad 112, upper pad 113, and internal wiring 114 may be formed of and/or include a conductive material, and may include, for example, copper (Cu), aluminum (Al), silver (Ag), tin (Sn), gold (Au), nickel (Ni), lead (Pb), titanium (Ti), chromium (Cr), and tungsten (W) or alloys thereof. The lower pad 112, upper pad 113, and internal wiring 114 may each be one of a ground pattern, a power pattern, or a signal pattern. The signal pattern may provide a path by which various signals, for example, data, address and/or control signals, are transmitted/received. The signal pattern may be connected to a latch (e.g., part of an integrated circuit of the semiconductor chip 130 or of the second semiconductor chip 150) to latch the signal value (e.g., representing a logic high or a logic low). The signal pattern may exclude ground connections, power connections, and the like, which may provide generally constant potentials during operation.

The connecting portion 120 may be disposed along a lateral edge of the substrate 110. For example, the first semiconductor chip 130 may be disposed in a central portion of the upper surface of the substrate 110, and the connecting portion 120 may be disposed to surround the first semiconductor chip 130. The connecting portion 120 may have a shape protruding or extending upwardly relative to the upper surface of the substrate 110 outside of the upper connection portion. In an example embodiment, in a plan view, the connecting portion 120 may have a frame shape having a first width W1 is a first lateral direction and a second width W2 in a second lateral direction. In an example embodiment, each of widths W1 and W2 of the connecting portion 120 may be in the range of 0.04 mm to 0.923 mm. In an example embodiment, the width W1 of the connecting portion 120 in an X-direction may be equal to the width W2 of the connecting portion 120 in a Y-direction, but the present disclosure is not limited thereto. In some example embodiments, the width W1 may be different from the width W2.

The connecting portion 120 may include a second insulating layer 121, a bonding pad 122, and a connection layer 123. The second insulating layer 121 may extend upwardly from an upper surface of the first insulating layer 111. The second insulating layer 121 may include the same material as the first insulating layer 111. For example, the second insulating layer 121 may include a thermosetting resin such as an epoxy resin, a thermoplastic resin such as polyimide, or a photosensitive insulating layer. The second insulating layer 121 may be formed integrally with the first insulating layer 111 and may be materially continuous therewith (e.g., formed of identical materials which may be provided by identical processes or formed of the same material provided in the same process). For example, boundaries may not be observed between the second insulating layer 121 and the first insulating layer 111.

The bonding pad 122 may be disposed at an upper surface of the connecting portion 120. For example, the bonding pad 122 may not be completely covered with the second insulating layer 121, and an upper surface of the bonding pad 122 may be exposed from the second insulating layer. The upper surface of the bonding pad 122 is illustrated as being coplanar with an upper surface of the second insulating layer 121, but the present disclosure is not limited thereto. The bonding pad 122 may extend in a horizontal direction. The bonding pad 122 may be electrically connected to the second semiconductor chip 150 as will be described below. The bonding pad 122 may also be electrically connected to at least one of the lower pads 112 through a connection layer 123 disposed between the bonding pad 122 and the lower pads 112.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

In an example embodiment, the upper surface of the substrate 110 may include a first region R1 and a second region R2 disposed at a level higher than that of the first region R1. For example, a portion of an upper surface of the substrate 110 on which the connecting portion 120 is disposed may be referred to as the second region R2, and a portion of an upper surface of the substrate 110 on which the connecting portion 120 is not disposed may be referred to as a first region R1. The second region R2 may be disposed to surround the first region R1. The upper pads 113 may be disposed in the first region R1.

A thickness of the substrate 110 in the first region R1 may be less than a thickness of the substrate 110 in the second region R2. The upper pad 113 of the substrate 110 may be disposed in the first region R1, and the bonding pad 122 may be disposed in the second region R2.

In an example embodiment, the substrate 110 may include a cavity C which may be defined laterally by the connecting portion 120. The cavity C may refer to a space surrounded by the connecting portion 120. For example, an internal surface 120_S1 of the connecting portion 120 and the upper surface of the first region R1 may define the cavity C. A side surface of the cavity C may correspond to the internal surface 120_S1 of the connecting portion 120, and a lower surface of the cavity C may correspond to the first region R1 of the upper surface of the substrate 110.

In an example embodiment, the first semiconductor chip 130 may be electrically connected to the substrate 110 through a chip connection terminal 132. For example, the chip connection terminal 132 may have a flip-chip connecting portion having a solder ball, a conductive bump, or a grid array such as a pin grid array, a ball grid array, or a land grid array. The first semiconductor chip 130 may include a chip pad 134 on a lower surface thereof, and the chip connection terminal 132 may connect the chip pad 134 to the upper pad 113 that is disposed on the substrate 110.

The chip connection terminal 132 may be formed of and/or include at least one of copper (Cu), nickel (Ni), tin (Sn), or an alloy including tin (Sn—Ag). For example, the chip connection terminal 132 may include a pillar portion connected to the chip pad 134 and a solder portion below the pillar portion. The pillar portion may be formed of and/or include at least one of copper (Cu) or nickel (Ni), and the solder portion may be formed of and/or include an alloy including tin (Sn—Ag).

The first semiconductor chip 130 may be a logic chip or a memory chip. The logic chip may include a microprocessor, an analog element, a digital signal processor, or a modem chip. The memory chip may include a volatile memory chip such as a Dynamic Random Access Memory (DRAM) or a Static Random Access Memory (SRAM), or a non-volatile memory chip such as a Phase-change Random Access Memory (PRAM), a Magnetoresistive Random Access Memory (MRAM), or a Ferroelectric Random Access Memory (FeRAM), or a Resistive Random Access Memory (RRAM). In an example embodiment, the first semiconductor chip 130 may be a logic chip, for example, a modem chip.

The underfill 140 may be disposed between the substrate 110 and the first semiconductor chip 130. The underfill 140 may fill a space between the first region R1 on the upper surface of the substrate 110 and a lower surface of the first semiconductor chip 130 and a space between the chip connection terminals 132. The underfill 140 may include an insulating polymer material, for example, an epoxy resin.

In an example embodiment, the underfill 140 may be disposed in the cavity C and may be disposed in the first region R1. The underfill 140 may not be disposed in the second region R2 and may be spaced apart from the bonding pad 122 of the connecting portion 120. For example, the bonding pad 122 may be disposed at a level higher than that of the underfill 140. In an example embodiment, the bonding pad 122 may be disposed at a level higher than that of an upper surface of the underfill 140 or a lower surface of the first semiconductor chip 130. Accordingly, according to example embodiments of the present disclosure, the bonding pad 122 may be prevented from being covered with the underfill 140, and reliability of the semiconductor package 100 may be improved.

The underfill 140 may not cover a side surface of the connecting portion 120, and may be separated from the connecting portion 120, but the present disclosure is not limited thereto.

The second semiconductor chip 150 may be disposed on the first semiconductor chip 130. For example, the second semiconductor chip 150 may be attached to an upper surface of the first semiconductor chip 130 by an adhesive layer 154 disposed at a lower surface thereof. The second semiconductor chip 150 may be a logic chip or a memory chip. In an example embodiment, the second semiconductor chip 150 may be a memory chip.

The second semiconductor chip 150 may be electrically connected to the connecting portion 120. For example, a chip pad 152 of the second semiconductor chip 150 may be disposed at an upper surface of the second semiconductor chip 150, and may be electrically connected to the bonding pad 122 by the bonding wire 160.

In an example embodiment, the second region R2 may be disposed at the same level as the upper surface of the second semiconductor chip 150. That is, the upper surface of the connecting portion 120 may be disposed at the same level as the upper surface of the second semiconductor chip 150. In some example embodiments, the upper surface of the connecting portion 120 may be disposed at a different level from the upper surface of the second semiconductor chip 150. In an example embodiment, the upper surface of the connecting portion 120 may be disposed at least on a level higher than that of the lower surface of the first semiconductor chip 130.

According to example embodiments of the present disclosure, since the bonding pad 122 is disposed in the second region R2 that is higher than the first region R1 on the upper surface of the substrate 110, the bonding wire 160 connecting the chip pad 152 of the second semiconductor chip 150 and the bonding pad 122 may be prevented from being excessively curved, thereby preventing adjacent bonding wires 160 from coming into contact with each other and being electrically short-circuited.

The encapsulant 170 may cover the substrate 110, the first semiconductor chip 130, the underfill 140, and the second semiconductor chip 150. The encapsulant 170 may be a resin including epoxy or polyimide. For example, the resin may include a bisphenol-group epoxy resin, a polycyclic aromatic epoxy resin, an o-Cresol Novolac Epoxy resin, a Biphenyl-group Epoxy resin, or a Naphthalene-group Epoxy resin.

The encapsulant 170 may further include a filler, a hardener, and a hardening catalyst. In an example embodiment, the encapsulant 170 may include a material having high thermal conductivity. For example, the filler may be aluminum oxide (Al₂O₃). In an example embodiment, a content of the filler in the encapsulant 170 may be about 90 wt % to about 92 wt %. Since the encapsulant 170 according to example embodiments of the present disclosure includes a material having high thermal conductivity, heat generated in the first and second semiconductor chips 130 and 150 may be effectively dissipated to the outside of the semiconductor package 100.

In an example embodiment, the encapsulant 170 may include a lower portion 172 and an upper portion 174. For example, a portion of the encapsulant 170 that is lower than the upper surface of the connecting portion 120 may be referred to as the lower portion 172, and a portion of the encapsulant 170 that is higher than the upper surface of the connecting portion 120 may be referred to as the upper portion 174. The lower portion 172 of the encapsulant 170 may cover side surfaces of the first semiconductor chip 130, the underfill 140, and the second semiconductor chip 150. The lower portion 172 of the encapsulant 170 may be in contact with the internal surface 120_S1 of the connecting portion 120. The upper portion 174 of the encapsulant 170 may be disposed on the lower portion 172 and may cover the connecting portion 120. For example, the upper portion 174 of the encapsulant 170 may be in contact with the upper surface of the connecting portion 120, that is, may be in contact with the second region R2. Additionally, a lateral surface of the upper portion 174 of the encapsulant 170 may be coplanar with an external surface 120_S2 of the connecting portion 120. A horizontal width of the upper portion 174 may be greater than a horizontal width of the lower portion 172.

According to example embodiments of the present disclosure, a volume of the encapsulant 170 may be reduced by the volume occupied by the connecting portion 120. Accordingly, a smaller amount of the encapsulant 170 may be used in a process of manufacturing the semiconductor package 100, and manufacturing costs may be reduced.

The external connection terminal 180 may be disposed at the lower surface of the substrate 110. The external connection terminal 180 may be electrically connected to the upper pad 113 through the lower pad 112 that is disposed at the lower surface of the substrate 110. The external connection terminal 180 may electrically connect the semiconductor package 100 to an external device such as a module substrate or main board. The external connection terminal 180 may be formed of and/or include a low melting point metal, for example, tin (Sn) or an alloy including tin (Sn) (for example, Sn—Ag—Cu).

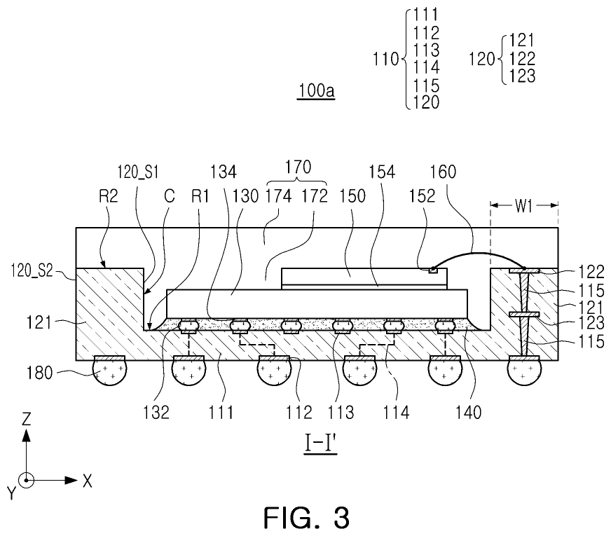

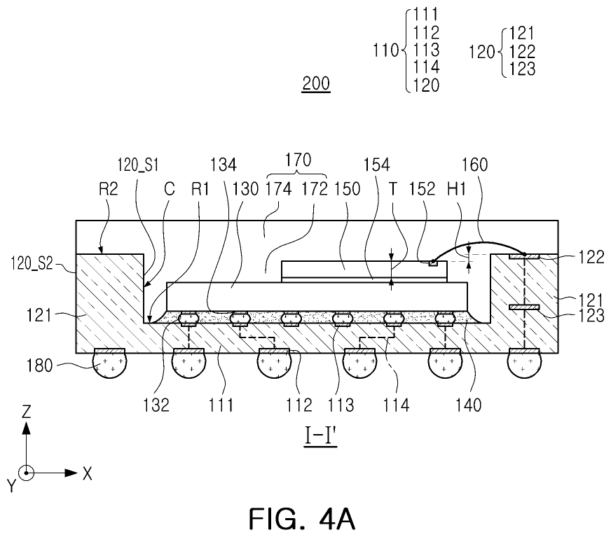

FIGS. 3 to 5 are vertical cross-sectional views of a semiconductor package according to example embodiments.

Referring to FIG. 3, a substrate 110 of a semiconductor package 100a may further include a connection via 115 electrically connecting a bonding pad 122 of the connecting portion 120 to one of lower pads 112. The connection vias 115 may be disposed between one of the lower pads 112 and a connection layer 123 and between the connection layer 123 and the bonding pad 122, and may extend vertically. In an example embodiment, a height of the connection vias 115 may be greater than a vertical distance between the lower pad 112 and the upper pad 113. In some example embodiments, the connection layer 123 may be omitted, and the connection via 115 may extend vertically from an upper surface of the lower pad 112 to a lower surface of the bonding pad 122.

Referring to FIG. 4A, a substrate 110 of a semiconductor package 200 may include a connecting portion 120 disposed at an edge of the substrate 110. In an example embodiment, an upper surface of the connecting portion 120 may be disposed at a level higher than that of a lower surface of a first semiconductor chip 130 and may be disposed at a level higher than that of an upper surface of a second semiconductor chip 150. For example, a vertical distance H1 between the upper surface of the connecting portion 120 and the upper surface of the second semiconductor chip 150 may be about 20% or less of a thickness T of the second semiconductor chip 150. When the vertical distance H1 between the upper surface of the connecting portion 120 and the upper surface of the second semiconductor chip 150 is 0% of the thickness T of the second semiconductor chip 150, the upper surface of the connecting portion 120 and the upper surface of the second semiconductor chip 150 may be disposed at the same level.

Referring to FIG. 4B, a substrate 110 of the semiconductor package 300 may include the connecting portion 120 disposed at an edge of the substrate 110. In an example embodiment, an upper surface of the connecting portion 120 may be disposed at a lower level than an upper surface of a second semiconductor chip 150. In an example embodiment, the upper surface of the connecting portion 120 may be disposed at least at a level higher than that of a lower surface of a first semiconductor chip 130. In an example embodiment, a vertical distance H2 between the upper surface of the connecting portion 120 and the upper surface of the second semiconductor chip 150 may be about 20% or less of the thickness T of the second semiconductor chip 150.

Referring to FIG. 5, a semiconductor package 400 may include an underfill 140 between a substrate 110 and a first semiconductor chip 130. In an example embodiment, the underfill 140 may completely cover a first region R1 of an upper surface of the substrate 110 and may be in contact with a side surface of the connecting portion 120.

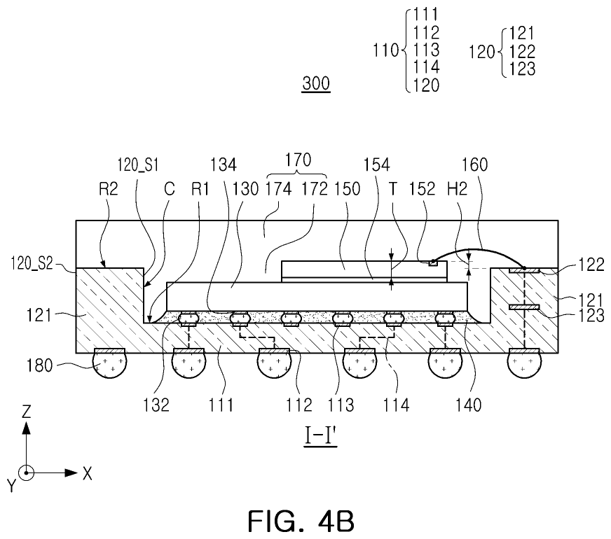

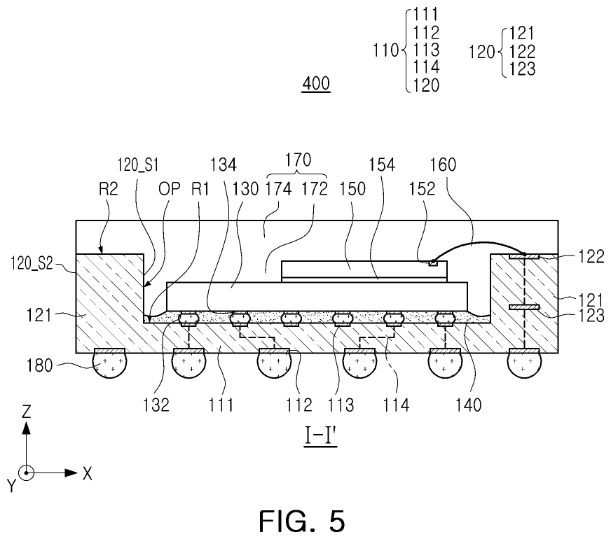

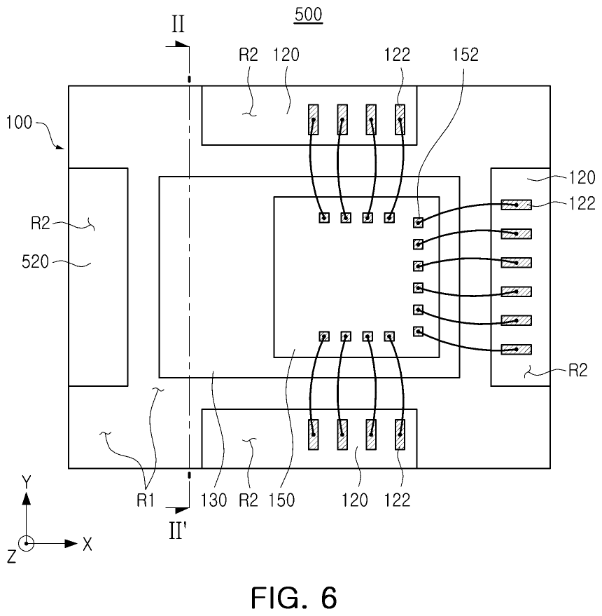

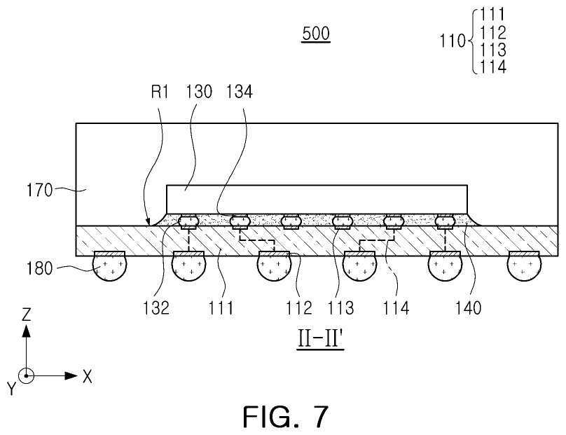

FIG. 6 is a plan view of a semiconductor package according to an example embodiment. FIG. 7 is a vertical cross-sectional view taken along line II-II′ of the semiconductor package illustrated in FIG. 6

Referring to FIGS. 6 and 7, a substrate 110 of a semiconductor package 500 may include connecting portions 120 and upper portions 520 that are each disposed at a respective edge of the substrate 110. In an example embodiment, the connecting portions 120 and the upper portions 520 may be disposed at a portion of an edge of substrate 110. For example, the connecting portions 120 and the upper portions 520 may be disposed in a central portion of each side surface of the substrate 110. In order to reduce warpage of the substrate 110, the connecting portions 120 and the upper portion 520 may be disposed symmetrically with respect to a central portion of an upper surface of the substrate 110.

The connecting portions 120 and the upper portions 520 may be disposed in second regions R2, and the second regions R2 may have upper surfaces at a level higher than that of an upper surface of the first region R1 of the substrate 110. Bonding pads 122 may be disposed in one of the second regions R2. The upper portion 520 may be disposed in one of the second regions R2 but may not include the bonding pads 122. For example, the upper portion 520 may consist of the second insulating layer 121.

The first region R1 may be disposed in a central portion and an edge of the upper surface of the substrate 110. For example, the first region R1 may be disposed in the central portion and a corner portion of the upper surface of the substrate 110.

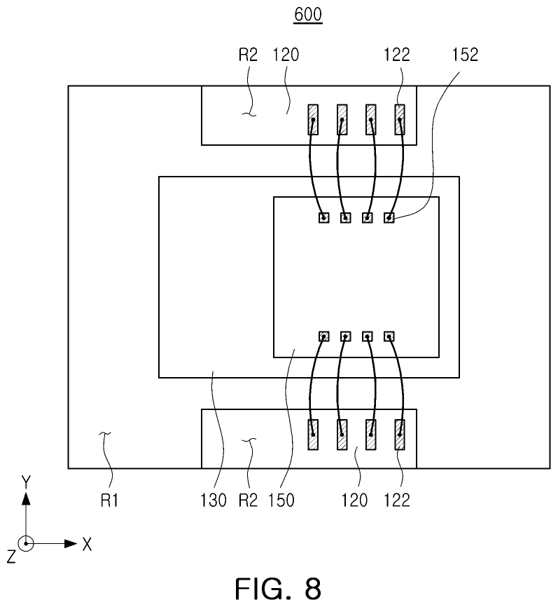

FIG. 8 is a plan view of a semiconductor package according to an example embodiment.

Referring to FIG. 8, a substrate 110 of a semiconductor package 600 may include connecting portions 120 disposed at edges of the substrate 110. In an example embodiment, the connecting portions 120 may be disposed at a portion of an edge of substrate 110. For example, the connecting portions 120 may be spaced apart from each other in the Y-direction with a first semiconductor chip 130 interposed therebetween. However, an arrangement structure of the connecting portions 120 illustrated in FIGS. 6 and 8 is illustrative and the present disclosure is not limited thereto.

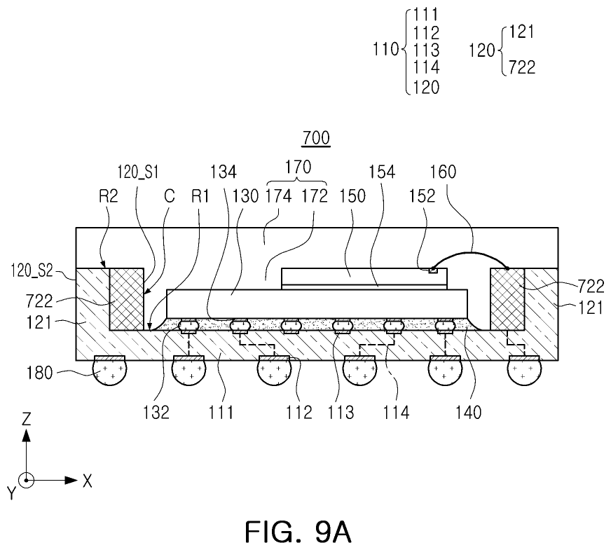

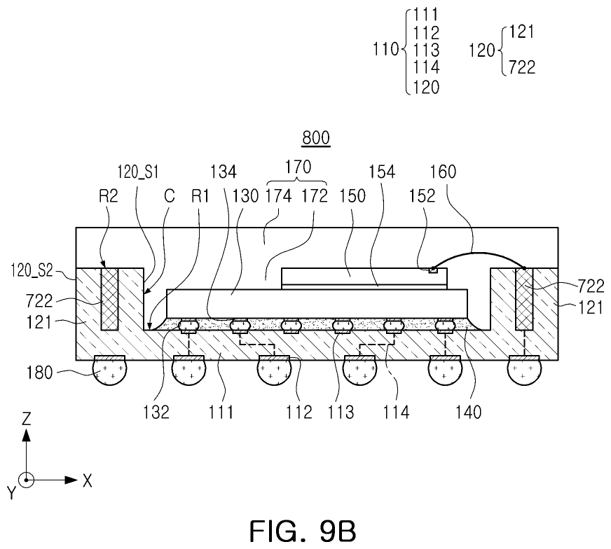

FIG. 9A is a vertical cross-sectional view of a semiconductor package according to an example embodiment.

Referring to FIG. 9A, a substrate 110 of a semiconductor package 700 may include the connecting portion 120 disposed at an edge of the substrate 110. In an example embodiment, the semiconductor package 700 may further include a conductive block 722 disposed adjacent to the second insulating layer 121 of the connecting portion. The conductive block 722 may be disposed closer to the first semiconductor chip 130 than the connecting portion 120. For example, the conductive block 722 may be disposed at an inner peripheral surface of the second insulating layer 121. The conductive block 722 may extend vertically from the first region R1 on an upper surface of the substrate 110, and an upper surface of the conductive block 722 may be coplanar with an upper surface of the second insulating layer 121 in the second region R2.

The conductive block 722 may be electrically connected to a second semiconductor chip 150. For example, a bonding wire 160 may be in contact with the conductive block 722, and the conductive block 722 may be electrically connected to a chip pad 152 through the bonding wire 160. The conductive block 722 may also be electrically connected to at least one of the lower pads 112. In an example embodiment, the substrate 110 may further include a conductive pad disposed at an upper surface of the first region R1 of the substrate 110 and in contact with a lower surface of the conductive block 722. The conductive pad may electrically connect the conductive block 722 to at least one of the lower pads 112.

FIG. 9B is a vertical cross-sectional view of a semiconductor package according to an example embodiment.

Referring to FIG. 9B, a substrate 110 of a semiconductor package 800 may include the connecting portion 120 disposed at an edge of the substrate 110. In an example embodiment, the connecting portion 120 may include the second insulating layer 121. The conductive block 722 may be disposed in the second insulating layer 121. For example, the conductive block 722 may be embedded in the second insulating layer 121, and side surfaces of the conductive block 722 may be covered with the second insulating layer 121 and may not be exposed. An upper surface of the conductive block 722 may be exposed without being covered with the second insulating layer 121. In an example embodiment, the upper surface of the conductive block 722 and an upper surface of the second insulating layer 121 may be coplanar with each other.

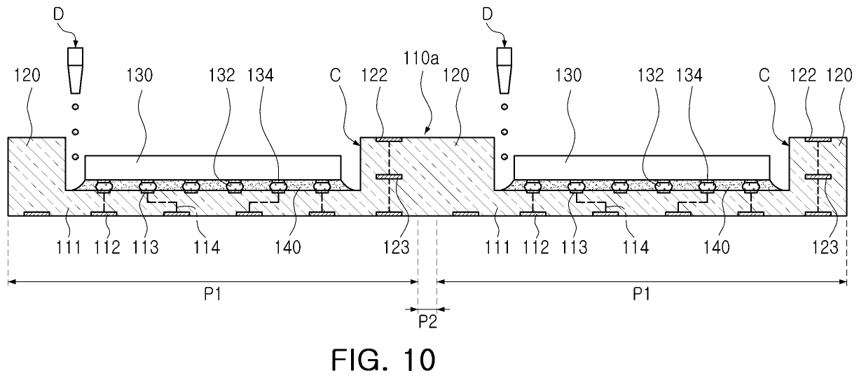

FIGS. 10 to 12 are diagrams for explaining a method of forming a semiconductor package according to example embodiments.

Referring to FIG. 10, a substrate structure 110a including the connecting portion 120 may be provided. The substrate structure 110a may include a first portion P1 and a second portion P2. The first portion P1 may be a portion constituting the semiconductor package 100, and the second portion P2 may be disposed between the first portions P1. The second portion may be removed by a sawing process described below.

The substrate structure 110a may further include a first insulating layer 111, a lower pad 112, an upper pad 113, and an internal wiring 114 disposed in the first portion P1. The connecting portions 120 may extend upwardly from an upper surface of a lower portion of the substrate structure 110a and define cavities C.

First semiconductor chips 130 may be mounted in the cavities C. In an example embodiment, the first semiconductor chips 130 may be mounted on the substrate structure 110a using a flip chip method. For example, chip pads 134 of the first semiconductor chips 130 and chip connection terminals 132 in contact with the upper pads 113 of the substrate structure 110a may be disposed below the first semiconductor chips 130.

An underfill material may be provided in the cavities C to form an underfill 140. For example, a dispenser D may provide the underfill material into the cavities C, and the underfill material may fill a space between the substrate structure 110a and lower surfaces of the first semiconductor chips 130 through a capillary phenomenon. Since a bonding pad 122 is disposed at a level higher than that of the first semiconductor chips 130, the bonding pad 122 may not be covered with the underfill 140.

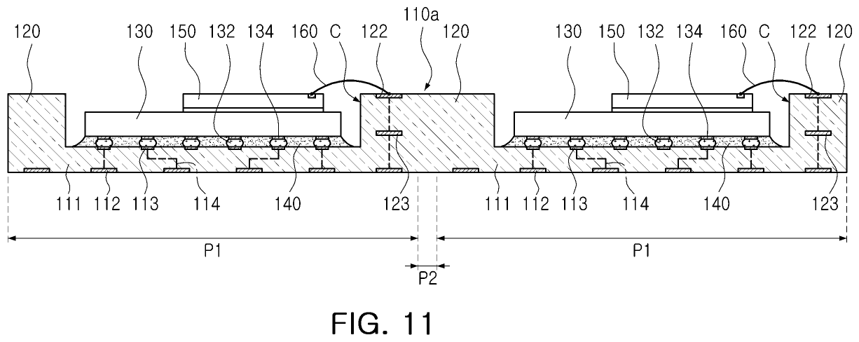

Referring to FIG. 11, second semiconductor chips 150 may be mounted on the first semiconductor chips 130, respectively. The second semiconductor chips 150 may be mounted using a wire bonding method, and may be electrically connected to the connecting portions 120. For example, the second semiconductor chips 150 may be electrically connected to the connecting portions 120 through bonding wires 160.

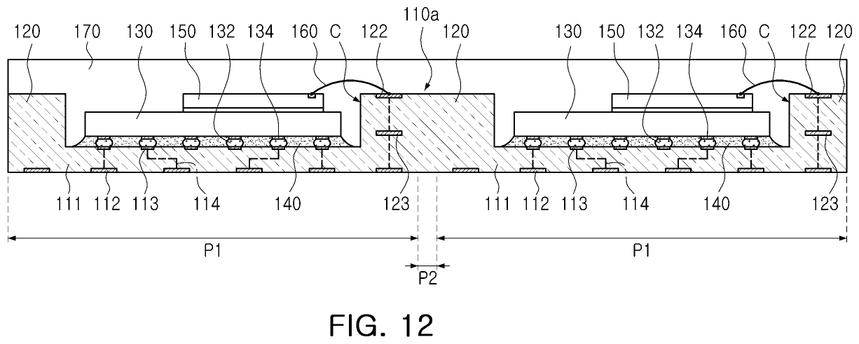

Referring to FIG. 12, an encapsulant 170 may be formed to cover the substrate structure 110a, the first semiconductor chips 130, the underfill 140, and the second semiconductor chips 150.

Referring again to FIG. 2, external connection terminals 180 may be formed on the lower pads 112. Then, the substrate structure 110a may be cut in a sawing process to form the substrates 110, and the semiconductor package 100 may be manufactured. In an example embodiment, the second portion P2 may be removed through the sawing process.

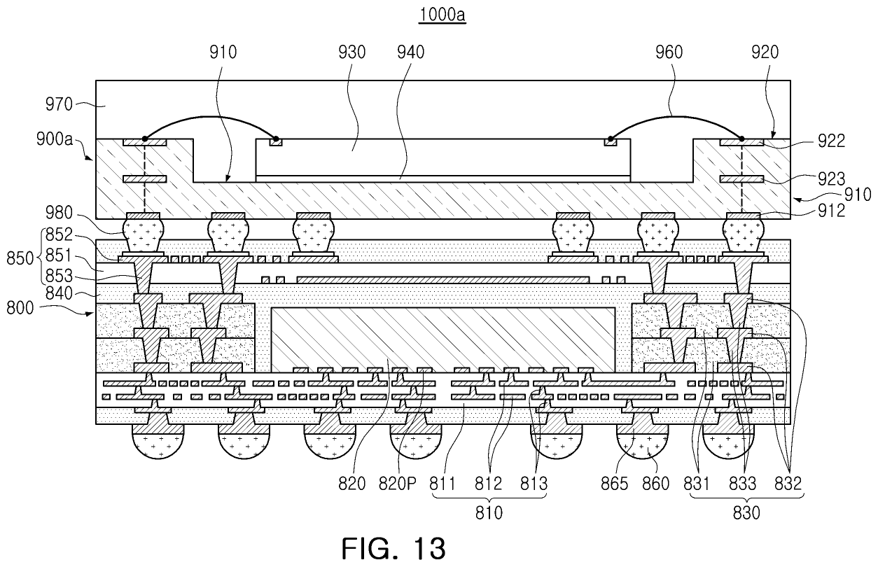

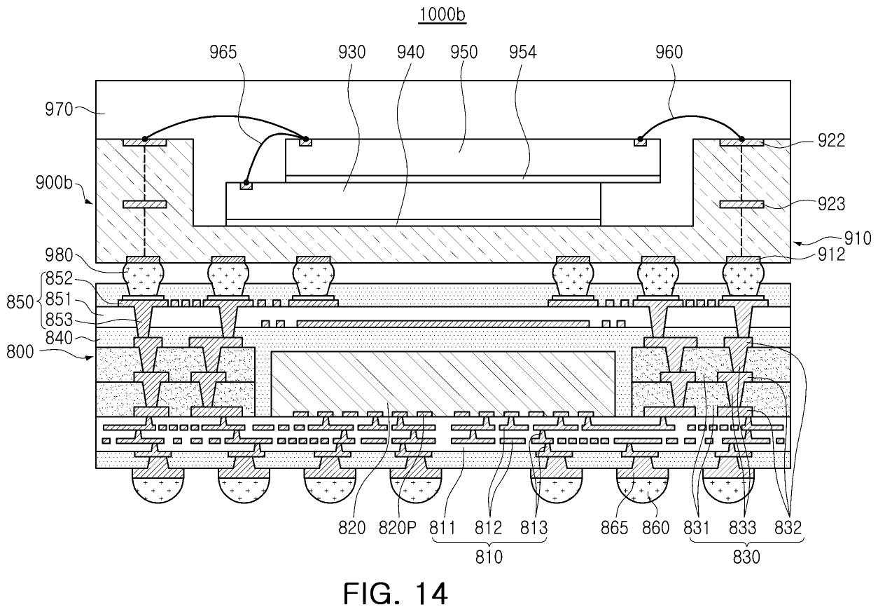

FIGS. 13 and 14 are vertical cross-sectional views of a semiconductor package according to example embodiments.

Referring to FIG. 13, a semiconductor package 1000a of an example embodiment may have a package-on-package structure including a first semiconductor package 800 and a second semiconductor package 900a.

The semiconductor first package 800 may include a lower redistribution structure 810, a lower semiconductor chip 820, a frame structure 830, and an encapsulant 840. According to an example embodiment, the first semiconductor package 800 may further include an upper redistribution structure 850.

The lower redistribution structure 810 is a support substrate on which the lower semiconductor chip 820 is mounted, and may include a lower insulating layer 811, a lower redistribution layer 812, and a lower redistribution via 813. The lower redistribution layer 812 may redistribute connection pads 820P of the lower semiconductor chip 820. The lower redistribution layer 812 may include a plurality of lower redistribution layers 812. The plurality of lower redistribution layers 812 may be electrically connected to each other through the lower redistribution via 813.

An underbump layer 865 and connection terminals 860 may be disposed below the lower redistribution structure 810. The underbump layer 865 may be disposed between a lowermost redistribution layer 812 and the connection terminals 860. The connection terminals 860 may connect a semiconductor package 1000 to an external device such as a module substrate or main board.

The lower semiconductor chip 820 may be disposed on the lower redistribution structure 810, and may include a connection pad 820P electrically connected to the lower redistribution layer 812. The lower semiconductor chip 820 may be disposed in the frame structure 830. The lower semiconductor chip 820 may be a bare integrated circuit (IC) in which no separate bumps or wiring layers are formed, but the present disclosure is not limited thereto, and the lower semiconductor chip 820 may be a packaged type of integrated circuit. The lower semiconductor chip 820 may be a logic chip or a memory chip, and in an example embodiment, the lower semiconductor chip 820 may be a logic chip.

The frame structure 830 may be disposed on the lower redistribution structure 810. The frame structure 830 may provide an electrical path connecting the lower redistribution layer 812 and the upper redistribution layer 852 around the lower semiconductor chip 820. The frame structure 830 may include an insulating resin layer 831, an interconnection layer 832, and an interconnection via 833. The interconnection layer 832 may be disposed on at least one of both surfaces of the insulating resin layer 831. The interconnection layer 832, together with the interconnection via 833, may provide an upper/lower electrical connection path of a package, and may serve to redistribute the connection pad 820P. The interconnection via 833 may electrically connect the interconnection layers 832 of different layers, and as a result, an electrical path may be formed in the frame structure 830. For example, the interconnection via 833 may electrically connect the interconnection layers 832 disposed at both surfaces of the insulating resin layer 831.

The encapsulant 840 may cover at least a portion of each of the lower semiconductor chip 820 and the frame structure 830. The encapsulant 840 may be a resin including epoxy or polyimide. For example, the encapsulant 840 may include the same material as the encapsulant 170 described with reference to FIG. 2.

The upper redistribution structure 850 may be disposed on the encapsulant 840, and may include an upper insulating layer 851, an upper redistribution layer 852, and an upper redistribution via 153 penetrating through the upper insulating layer 851 and electrically connecting the upper redistribution layer 852 and the interconnection layers 832. Since the upper insulating layer 851, the upper redistribution layer 852, and the upper redistribution via 153 have characteristics identical or similar to the lower insulating layer 811, the lower redistribution layer 812, and the lower redistribution via 813 described above, overlapping descriptions thereof will be omitted.

The second semiconductor package 900a may include a substrate 910, a first upper semiconductor chip 930, an adhesive layer 940, a bonding wire 960, an encapsulant 970, and a package connection terminal 980. The substrate 910, the bonding wire 960, the encapsulant 970, and the package connection terminal 980 have characteristics identical or similar to the substrate 110, the bonding wire 160, the encapsulant 170, and the external connection terminal 180 described with reference to FIG. 2. For example, the substrate 910 may include a lower pad 912 and a connecting portion 920. The connecting portion 920 may include a bonding pad 922 and a connection layer 923.

In an example embodiment, the first upper semiconductor chip 930 may be a memory chip. The first upper semiconductor chip 930 may be mounted using a wire bonding method. For example, the adhesive layer 940 may be disposed at a lower surface of the first upper semiconductor chip 930, and the first upper semiconductor chip 930 may be attached to the substrate 910 by the adhesive layer 940. The first upper semiconductor chip 930 may be electrically connected to the connecting portion 920 through the bonding wire 960. For example, the bonding wire 960 may connect the first upper semiconductor chip 930 to the bonding pad 922.

The first upper semiconductor chip 930 may be electrically connected to the substrate 910 and may be electrically connected to the first semiconductor package 800 through the package connection terminal 980.

Referring to FIG. 14, a semiconductor package 1000b of an example embodiment may have a package-on-package structure including a first semiconductor package 800 and a second semiconductor package 900b.

In an example embodiment, the second semiconductor package 900b may include a first upper semiconductor chip 930 and a second upper semiconductor chip 950 mounted on the substrate 910. In an example embodiment, the first upper semiconductor chip 930 and the second upper semiconductor chip 950 may be memory chips. The first upper semiconductor chip 930 and the second upper semiconductor chip 950 may be mounted on the substrate 910 using a wire bonding method. For example, an adhesive layer 940 and an adhesive layer 954 may be disposed at lower surfaces of the first upper semiconductor chip 930 and the second upper semiconductor chip 950, and the adhesive layer 940 and the adhesive layer 954 may be in contact with an upper surface of the substrate 910 and an upper surface of the first upper semiconductor chip 930, respectively.

The first upper semiconductor chip 930 and the second upper semiconductor chip 950 may be electrically connected to the connecting portion 920 of the substrate 910 by a first bonding wire 960 and a second bonding wire 965. For example, the second bonding wire 965 may electrically connect the first upper semiconductor chip 930 to the second upper semiconductor chip 950. The first bonding wire 960 may electrically connect the second upper semiconductor chip 950 to the bonding pad 922 of the connecting portion 920.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor package, comprising:
a substrate including a first region, a second region, a connecting portion in the second region, the first region of the substrate having an upper pad disposed at an upper surface thereof and the connecting portion having a bonding pad disposed at an upper surface thereof;
a first semiconductor chip disposed on the substrate in the first region;
an underfill between the substrate and the first semiconductor chip;
a second semiconductor chip disposed on the first semiconductor chip; and
an encapsulant covering the substrate, the first semiconductor chip, and the second semiconductor chip,
wherein the bonding pad is disposed at a level higher than that of the upper pad.

2. The semiconductor package of claim 1, wherein the connecting portion surrounds the first semiconductor chip in a horizontal direction.

3. The semiconductor package of claim 1, wherein the connecting portion extends upwardly relative to the upper surface of the substrate in the first region,
the substrate includes a first insulating layer in the first region and the first insulating layer and a second insulating layer in the second region, and
the connecting portion includes the second insulating layer,
wherein the first insulating layer and the second insulating layer are formed integrally with the same material.

4. The semiconductor package of claim 1, wherein the connecting portion further comprises at least one connection via electrically connecting a lower pad of the substrate to the bonding pad.

5. The semiconductor package of claim 4, wherein the connecting portion further comprises a connection layer disposed between the lower pad and the bonding pad, and
the at least one connection via electrically connects the connection layer to the lower pad and the bonding pad.

6. The semiconductor package of claim 1, wherein an upper surface of the connecting portion is disposed at a level higher than that of a lower surface of the first semiconductor chip.

7. The semiconductor package of claim 6, wherein a vertical distance between an upper surface of the connecting portion and an upper surface of the second semiconductor chip is 20% or less of a thickness of the second semiconductor chip.

8. The semiconductor package of claim 1, wherein the encapsulant comprises a filler including aluminum oxide.

9. The semiconductor package of claim 8, wherein a content of the filler in the encapsulant is in a range of 90 wt % to 92 wt %.

10. The semiconductor package of claim 1, wherein the encapsulant comprises a lower portion lower than an upper surface of the connecting portion and an upper portion higher than the upper surface of the connecting portion, and
a horizontal width of the upper portion of the encapsulant is greater than the horizontal width of the lower portion of the encapsulant.

11. The semiconductor package of claim 10, wherein a side surface of the upper portion of the encapsulant is coplanar with an external surface of the connecting portion.

12. The semiconductor package of claim 1, wherein the underfill is in contact with an internal surface of the connecting portion.

13. The semiconductor package of claim 1, wherein a horizontal width of the connecting portion is in the range of 0.04 mm to 0.923 mm.

14. A semiconductor package, comprising:
a substrate having an upper surface including a first region and a second region;
at least one semiconductor chip stacked on the first region of the substrate;
a bonding wire electrically connecting an uppermost semiconductor chip from among the at least one semiconductor chip to the substrate; and
an encapsulant covering the substrate and the at least one semiconductor chip,
wherein an upper surface of the second region is disposed at a level higher than that of an upper surface of the first region, and
the substrate comprises a bonding pad disposed at an upper surface of the second region.

15. The semiconductor package of claim 14, wherein the first region is disposed in a central portion of the upper surface of the substrate, and
the second region is disposed at an edge of the upper surface of the substrate.

16. The semiconductor package of claim 15, wherein the first region further extends to a corner portion of the upper surface of the substrate, and
the second region is disposed in a portion of an edge of the upper surface of the substrate.

17. The semiconductor package of claim 14, wherein a thickness of the substrate in the second region is thicker than a thickness of the substrate in the first region.

18. The semiconductor package of claim 14, wherein the at least one semiconductor chip comprises a first semiconductor chip and a second semiconductor chip on the first semiconductor chip, and
the second semiconductor chip is electrically connected to the bonding pad by the bonding wire.

19. The semiconductor package of claim 18, further comprising:
an adhesive layer disposed between the first semiconductor chip and an upper surface of the substrate.

20. A semiconductor package, comprising:
a substrate including a connecting portion defining a cavity, the connecting portion including a bonding pad;
a first semiconductor chip disposed on the substrate and disposed in the cavity;
an underfill between the substrate and the first semiconductor chip;
a second semiconductor chip disposed on the first semiconductor chip;
a bonding wire connecting the second semiconductor chip and the bonding pad; and
an encapsulant covering the substrate, the first semiconductor chip, the second semiconductor chip, and the bonding wire,
wherein the connecting portion is disposed to surround the first semiconductor chip, and
the bonding pad is disposed at a level higher than that of a lower surface of the first semiconductor chip, and
a lower portion of the encapsulant is in contact with an internal surface of the connecting portion, and a side surface of an upper portion of the encapsulant is coplanar with an external surface of the connecting portion.
